(19) United States
(12) Patent Application Publication
(10) Pub. No.: US 2023/0400758 A1
(43) Pub. Date: Dec. 14, 2023

(54) EXTREME ULTRAVIOLET (EUV) PHOTOMASK

(71) Applicant: Samsung Electronics Co., Ltd., Suwon-si (KR)

(72) Inventors: Yigwon KIM, Suwon-si (KR); Sangjin KIM, Suwon-si (KR); Jihun LEE, Suwon-si (KR); Jinhee JANG, Suwon-si (KR); Jeonghyun KIM, Suwon-si (KR)

(73) Assignee: Samsung Electronics Co., Ltd., Suwon-si (KR)

(21) Appl. No.: 18/317,328

(22) Filed: May 15, 2023

(30) Foreign Application Priority Data
Jun. 8, 2022 (KR) 10-2022-0069750

(51) Int. Cl. G03F 1/22

(52) U.S. Cl. CPC G03F 1/22

(57) ABSTRACT

An extreme ultraviolet (EUV) photomask may include a mask structure including a main region, a scribe lane region surrounding the main region, buffer regions outside the scribe lane region and apart from each other and each having a same first width, and a black border region outside the buffer regions. The buffer regions may include a first buffer region, a second buffer region, and a third buffer region. The black border region may include a first corner region, a second corner region, and a third corner region. The first corner region may contact the first buffer region and the second buffer region. The second corner region may contact the first buffer region, the third buffer region, and a side of the scribe lane region. The third corner region may contact the second buffer region and the third buffer region.

### CROSS-REFERENCE TO RELATED APPLICATION

This application is based on and claims priority under 35 U.S.C. § 119 to Korean Patent Application No. 10-2022-0069750, filed on Jun. 8, 2022 in the Korean Intellectual Property Office, the disclosure of which is incorporated by reference herein in its entirety.

### BACKGROUND

Inventive concepts relate to an extreme ultraviolet (EUV) photomask, and more particularly, to an EUV photomask including a black border region and a buffer region.

In semiconductor manufacturing processes, to implement semiconductor devices on semiconductor substrates, photolithography processes may be performed. In particular, along with the trend of down-scaling of semiconductor devices, photolithography processes using EUV light have been proposed. In photolithography processes using EUV light, exposure processes may be performed using reflective masks.

### SUMMARY

Inventive concepts provide an EUV photomask capable of limiting and/or preventing pattern defects from being generated on a semiconductor substrate.

According to an embodiment of inventive concepts, an extreme ultraviolet (EUV) may include a mask structure including a main region, a scribe lane region surrounding the main region, a plurality of buffer regions outside the scribe lane region and apart from each other, and a black border region outside the plurality of buffer regions. The plurality of buffer regions may a first buffer region, a second buffer region, and a third buffer region. A first width of the first buffer region, a first width of the second buffer region, and a first width of the third buffer region may be equal to each other. The scribe lane region may include a marker region at one corner thereof. The first buffer region may contact a first side of the scribe lane region and may extend therealong. The second buffer region may contact a second side of the scribe lane region and may extend therealong. The third buffer region may include a first sub-buffer region, a second sub-buffer region, and a third sub-buffer region. The first sub-buffer region may contact a third side of the scribe lane region and may extend therealong. The second sub-buffer region may contact a fourth side of the scribe lane region and may extend therealong. The third sub-buffer region may surround the marker region and may contact the first sub-buffer region and the second sub-buffer region. The black border region may include a first corner region, a second corner region, and a third corner region. The first corner region may contact the first buffer region and the second buffer region. The second corner region may contact the first buffer region, the first sub-buffer region, and the third side of the scribe lane region. The third corner region may contact the second buffer region and the second sub-buffer region.

According to an embodiment of inventive concepts, an extreme ultraviolet (EUV) mask may include a mask structure including a main region, a scribe lane region surrounding the main region, a plurality of buffer regions outside the scribe lane region and apart from each other, and a black border region outside the plurality of buffer regions. The plurality of buffer regions may include a first buffer region, a second buffer region, a third buffer region, and a fourth buffer region. A first width of the first buffer region, a first width of the second buffer region, a first width of the third buffer region, and a first width of the fourth buffer region may be equal to each other. The scribe lane region may include a marker region at one corner thereof. The marker region may include a marker pattern region, a marker blocking region surrounding a portion of the marker pattern region, and a marker variable region surrounding a remaining portion of the marker pattern region. The first buffer region may contact a first side of the scribe lane region and may extend therealong. The second buffer region may contact a second side of the scribe lane region and may extend therealong. The third buffer region may contact a third side of the scribe lane region and may extend therealong. The third buffer region may contact the marker region. The fourth buffer region may contact a fourth side of the scribe lane region and may extend therealong, and the fourth buffer region may contact the marker region. The black border region may include a first corner region, a second corner region, and a third corner region. The first corner region may contact the first buffer region and the second buffer region. The second corner region may contact the first buffer region and the third buffer region. The third corner region may contact the second buffer region and the fourth buffer region.

According to an embodiment of inventive concepts, an extreme ultraviolet (EUV) mask may include a mask structure including a main region, a scribe lane region surrounding the main region and having a rectangular shape, a plurality of buffer regions outside the scribe lane region and apart from each other, and a black border region outside the plurality of buffer region. The plurality of buffer regions may include a first buffer region, a second buffer region, a third buffer region, and a fourth buffer region. A first width of the first buffer region, a first width of the second buffer region, a first width of the third buffer region, and a first width of the fourth buffer region may be equal to each other. The scribe lane region may include a first marker region, a second marker region, a third marker region, and a fourth marker region, respectively located at corners of the scribe lane region. The first marker region, the second marker region, the third marker region, and the fourth marker regions each may include a marker pattern region and a marker blocking region surrounding a portion of the marker pattern region. The first buffer region may contact a first side of the scribe lane region and may extend therealong. The second buffer region may contact a second side of the scribe lane region and may extend therealong. The third buffer region may contact a third side of the scribe lane region and may extend therealong. The fourth buffer region may contact a fourth side of the scribe lane region and may extend therealong. The black border region may include a first corner region, a second corner region, a third corner region, and a fourth corner region. The first corner region may contact the first buffer region, the second buffer region, and the first marker region. The second corner region may contact the first buffer region, the third buffer region, and the second marker region. The third corner region may contact the second buffer region, the fourth buffer region, and the third marker region. The fourth corner region may contact the third buffer region, the fourth buffer region, and the fourth marker region.

### BRIEF DESCRIPTION OF THE DRAWINGS

Embodiments of inventive concepts will be more clearly understood from the following detailed description taken in conjunction with the accompanying drawings in which:

FIGS. 1A and 1B are configuration diagrams schematically illustrating an extreme ultraviolet (EUV) exposure device according to an embodiment;

FIG. 2 is a plan view schematically illustrating an EUV photomask according to an embodiment;

FIG. 3 is a cross-sectional view of the EUV photo mask of FIG. 2, taken along the line A-A′ of FIG. 2;

FIGS. 4A and 4B are diagrams each illustrating a method of transferring a mask pattern onto a substrate by exposure using an EUV photomask;

FIG. 5 is a plan view schematically illustrating an EUV photomask according to an embodiment;

FIG. 6 is a plan view schematically illustrating an EUV photomask according to an embodiment;

FIG. 7 is a flowchart schematically illustrating a method of fabricating an EUV photomask, according to an embodiment; and

FIGS. 8A to 8D are cross-sectional views schematically illustrating processes of a method of fabricating an EUV photomask, according to an embodiment, respectively.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the presented embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments of inventive concepts will be described in detail with reference to the accompanying drawings. Like components are denoted by like reference numerals throughout the specification, and repeated descriptions thereof are omitted.

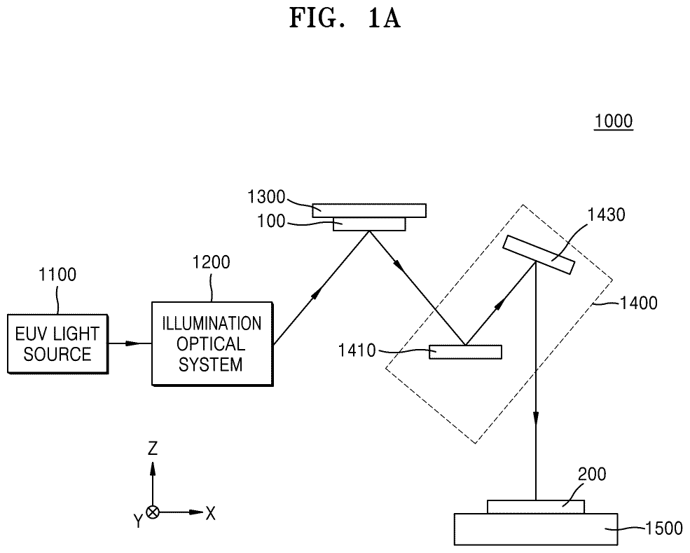

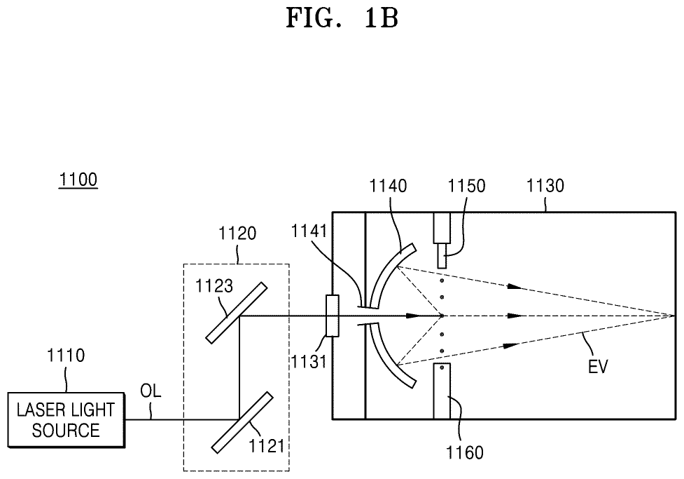

FIGS. 1A and 1B are configuration diagrams schematically illustrating an extreme ultraviolet (EUV) exposure device 1000 according to an embodiment.

Referring to FIGS. 1A and 1B, the EUV exposure device 1000 may include an EUV light source 1100, an illumination optical system 1200, a photomask support 1300, a projection optical system 1400, and a substrate stage 1500.

The EUV light source 1100 may generate and output EUV light EV having a high energy density. For example, the EUV light EV emitted from the EUV light source 1100 may have a wavelength of about 4 nm to about 124 nm. In some embodiments, the EUV light EV may have a wavelength of about 4 nm to about 20 nm, for example, a wavelength of 13.5 nm.

The EUV light source 1100 may include a plasma-based light source or a synchrotron radiation light source. Here, the plasma-based light source refers to a light source in which plasma is generated and light emitted by the plasma is used, and may include a laser produced plasma light source, a discharge produced plasma light source, or the like.

The EUV light source 1100 may include a laser light source 1110, a transfer optical system 1120, a vacuum chamber 1130, a collector mirror 1140, a droplet generator 1150, and a droplet catcher 1160.

The laser light source 1110 may be configured to output a laser beam OL. For example, the laser light source 1110 may output a carbon dioxide laser beam. The laser beam OL output from the laser light source 1110 may be incident on a window 1131 of the vacuum chamber 1130 through a plurality of reflective mirrors 1121 and 1123 included in the transfer optical system 1120, and be introduced into the vacuum chamber 1130.

An aperture 1141, through which the laser beam OL may pass, is formed in a central region of the collector mirror 1140, and the laser beam OL may be introduced into the vacuum chamber 1130 through the aperture 1141 of the collector mirror 1140.

The droplet generator 1150 may generate a droplet, which generates the EUV light EV, by interacting with the laser beam OL, and may provide the droplet into the vacuum chamber 1130. The droplet may include at least one of tin (Sn), lithium (Li), and xenon (Xe). For example, the droplet may include at least one of tin (Sn), a tin compound (for example, SnBr₄, SnBr₂, or SnH), and a tin alloy (for example, Sn—Ga, Sn—In, or Sn—In—Ga).

The droplet catcher 1160 is located under the droplet generator 1150 and may be configured to collect droplets that have not reacted with the laser beam OL. The droplets provided by the droplet generator 1150 may generate the EUV light EV by reacting with the laser beam OL introduced into the vacuum chamber 1130. The collector mirror 1140 may emit the EUV light EV to the illumination optical system 1200 arranged outside the vacuum chamber 1130, by collecting and reflecting the EUV light EV.

The illumination optical system 1200 may include a plurality of reflective mirrors and may transfer the EUV light EV, which is emitted from the EUV light source 1100, to an EUV photomask 100. For example, the EUV light EV emitted from the EUV light source 1100 may be reflected by a reflective mirror in the illumination optical system 1200 and may be incident on the EUV photomask 100 arranged on the photomask support 1300.

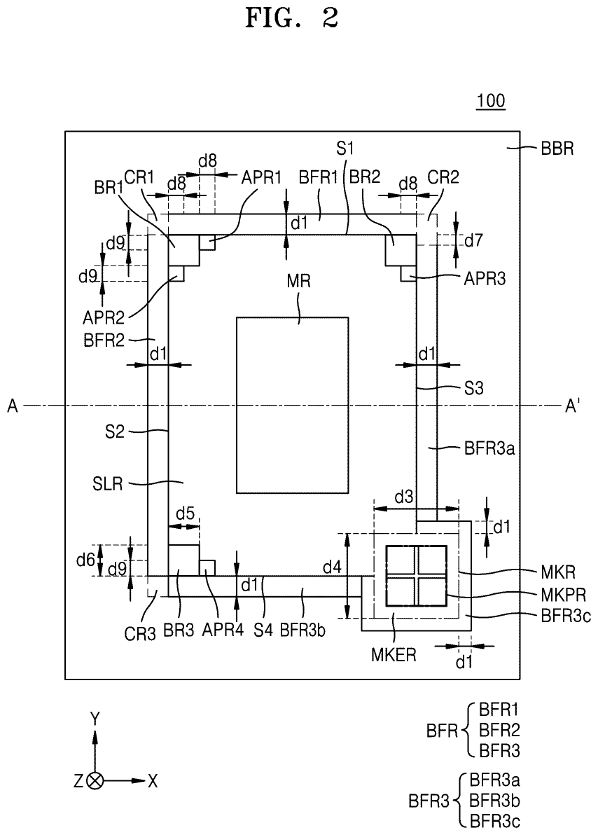

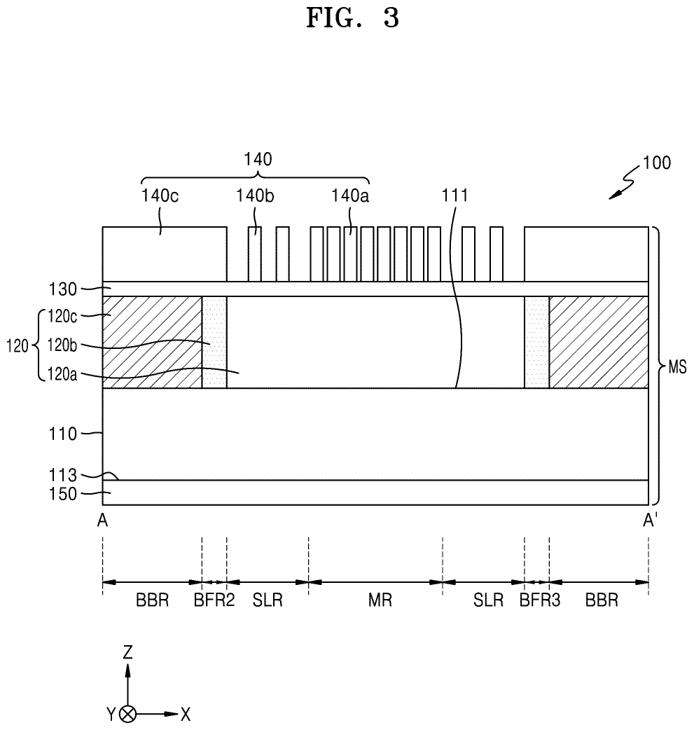

The EUV photomask 100 may be a reflective mask including a reflective area and a non-reflective (or medium-reflective) area. Here, the reflective area may include a main region MR (see FIGS. 2 and 3) and a scribe lane region SLR (see FIGS. 2 and 3), and the non-reflective (or medium-reflective) area may include a buffer region BFR (see FIGS. 2 and 3) and a black border region BBR (see FIGS. 2 and 3). The EUV photomask 100 according to an embodiment will be described below in detail.

The EUV photomask 100 reflects the EUV light EV, which is incident through the illumination optical system 1200, and thus causes the EUV light EV to be incident on the projection optical system 1400. Specifically, the EUV photomask 100 structuralizes light, which is incident from the illumination optical system 1200, into projection light, based on the shape of a pattern on the reflective area of a mask substrate, and causes the projection light to be incident on the projection optical system 1400. The projection light may be structuralized through a diffraction order of at least 2 due to the EUV photomask 100. The projection light may be incident on the projection optical system 1400 while having information about the pattern shape of the EUV photomask 100, and may form an image, which corresponds to the pattern shape of the EUV photomask 100, on a semiconductor substrate 200 through the projection optical system 1400.

The projection optical system 1400 may include a plurality of reflective mirrors 1410 and 1430. Although two reflective mirrors 1410 and 1430 are shown in the projection optical system 1400 in FIG. 1A, this is for convenience of description, and the projection optical system 1400 may include more than two reflective mirrors. For example, the projection optical system 1400 may include 4 to 8 reflective mirrors. However, the number of reflective mirrors included in the projection optical system 1400 is not limited to the numerical values set forth above.

The semiconductor substrate 200 may be arranged on the substrate stage 1500. The substrate stage 1500 may move in an X direction and a Y direction on an X-Y plane and may also move in a Z direction that is perpendicular to the X-Y plane. By the movement of the substrate stage 1500, the semiconductor substrate 200 may also move in the X direction, the Y direction, and the Z direction in the same manner.

FIG. 2 is a plan view schematically illustrating the EUV photomask 100 according to an embodiment. FIG. 3 is a cross-sectional view of the EUV photomask 100, taken along the line A-A′ of FIG. 2.

Referring to FIG. 2, the EUV photomask 100 may include a main region MR, a scribe lane region SLR, a buffer region BFR, and a black border region BBR outside the buffer region BFR.

The main region MR may transfer circuit layout patterns onto the semiconductor substrate 200 (see FIG. 1A).

The scribe lane region SLR may surround the main region MR. For example, the scribe lane region SLR may transfer a test device layout pattern for testing a semiconductor device onto the semiconductor substrate 200.

In an embodiment, the scribe lane region SLR may include a marker region MKR at one corner thereof. A portion of the marker region MKR may protrude from the one corner of the scribe lane region SLR. Specifically, when a rectangular shape is taken as a reference, blocking regions (for example, BR1, BR2, and BR3) described below may be respectively located inside three corners of the rectangular shape, a portion of the marker region MKR may protrude from the remaining one corner of the rectangular shape, and the remaining portion of the marker region MKR may be located inside the remaining one corner of the rectangular shape. The marker region MKR may have, for example, a rectangular shape. In this case, a first horizontal length d3 and a second horizontal length d4 of the marker region MKR may be equal to each other. Here, the first horizontal direction refers to the X direction, the second horizontal direction refers to the Y direction, and the first horizontal direction and the second horizontal direction are respectively interpreted below as having the same meanings as set forth above unless otherwise defined. For example, each of the first horizontal length d3 and the second horizontal length d4 of the marker region MKR may be, but is not limited to, 50 mm.

The marker region MKR may include a marker pattern region MKPR and a marker edge region MKER. The marker pattern region MKPR may transfer an alignment layout pattern allowing a location, to which a pattern is transferred on the semiconductor substrate 200, to be identified. For example, the marker pattern region MKPR may transfer, but is not limited to, the alignment layout pattern having a cross shape. The marker edge region MKER may surround the marker pattern region MKPR.

In an embodiment, the scribe lane region SLR may further include a first blocking region BR1, a second blocking region BR2, and a third blocking region BR3 respectively inside the remaining corners except for the one corner at which the marker region MKR is located. Specifically, the first blocking region BR1 may be located inside the corner corresponding to a vertex at which a first side S1 and a second side S2 of the scribe lane region SLR meet each other, the second blocking region BR2 may be located inside the corner corresponding to a vertex at which the first side S1 and a third side S3 of the scribe lane region SLR meet each other, and the third blocking region BR3 may be located inside the corner corresponding to a vertex at which the second side S2 and a fourth side S4 of the scribe lane region SLR meet each other. Here, the first side S1 and the fourth side S4 of the scribe lane region SLR may be opposite to each other, and the second side S2 and the third side S3 of the scribe lane region SLR may be opposite to each other.

In an embodiment, each of the first blocking region BR1, the second blocking region BR2, and the third blocking region BR3 may have a square shape. In this case, a first horizontal length d5 of each of the first blocking region BR1, the second blocking region BR2, and the third blocking region BR3 may be equal to a second horizontal length d6 of each of the first blocking region BR1, the second blocking region BR2, and the third blocking region BR3.

In an embodiment, the first horizontal length d5 set forth above may be 0.5 times the first horizontal length d3 of the marker region MKR, and the second horizontal length d6 set forth above may be 0.5 times the second horizontal length d4 of the marker region MKR.

The buffer region BFR may be arranged outside the scribe lane region SLR. As described below, the buffer region BFR may be a region to which a portion of heat generated during heat treatment on the black border region BBR is conducted.

The buffer region BFR may include a first buffer region BFR1, a second buffer region BFR2, and a third buffer region BFR3.

The first buffer region BFR1 may contact the first side S1 of the scribe lane region SLR and extend therealong. The second buffer region BFR2 may contact the second side S2 of the scribe lane region SLR and extend therealong. For example, each of the first buffer region BFR1 and the second buffer region BFR2 may have, but is not limited to, a rectangular shape.

The third buffer region BFR3 may include a first sub-buffer region BFR3a, a second sub-buffer region BFR3b, and a third sub-buffer region BFR3c. The first sub-buffer region BFR3a may contact the third side S3 of the scribe lane region SLR and extend therealong. The second sub-buffer region BFR3b may contact the fourth side S4 of the scribe lane region SLR and extend therealong. Each of the first sub-buffer region BFR3a and the second sub-buffer region BFR3b may have, for example, a rectangular shape. The third sub-buffer region BFR3c may surround a portion of the marker region MKR and contact the first sub-buffer region BFR3a and the second sub-buffer region BFR3b. Specifically, the third sub-buffer region BFR3c may surround the remaining portion of a perimeter of the marker edge region MKER of the marker region MKR except for a portion of the perimeter thereof located inside the scribe lane region SLR, and may contact the first sub-buffer region BFR3a and the second sub-buffer region BFR3b.

In an embodiment, the first buffer region BFR1, the second buffer region BFR2, and the third buffer region BFR3 may be arranged apart from each other. As described below, separated spaces between the first buffer region BFR1, the second buffer region BFR2, and the third buffer region BFR3 may be respectively filled with a first corner region CR1, a second corner region CR2, and a third corner region CR3.

In an embodiment, the first buffer region BFR1, the second buffer region BFR2, and the third buffer region BFR3 may extend while having the same first width d1. In an embodiment, the first width d1 of each of the first to third buffer regions BFR1 to BFR3 may be about 4 μm to about 8 μm.

The black border region BBR may be arranged outside the first to third buffer regions BFR1 to BFR3. As described below, the black border region BBR may limit and/or prevent light incident on the EUV photomask 100 from being reflected onto the semiconductor substrate 200.

The black border region BBR may include the first corner region CR1, the second corner region CR2, and the third corner region CR3.

The first corner region CR1 may contact the first buffer region BFR1 and the second buffer region BFR2. The first corner region CR1 may have, for example, a square shape.

The second corner region CR2 may contact the first buffer region BFR1, the first sub-buffer region BFR3a, and a portion of the third side S3 of the scribe lane region SLR. The second corner region CR2 may have, for example, a rectangular shape.

The third corner region CR3 may contact the second buffer region BFR2 and the second sub-buffer region BFR3b. The third corner region CR3 may have, for example, a square shape.

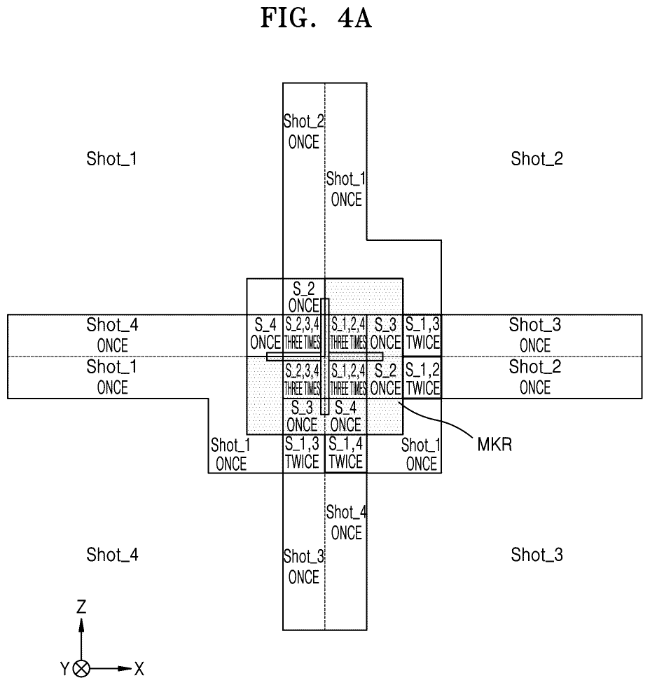

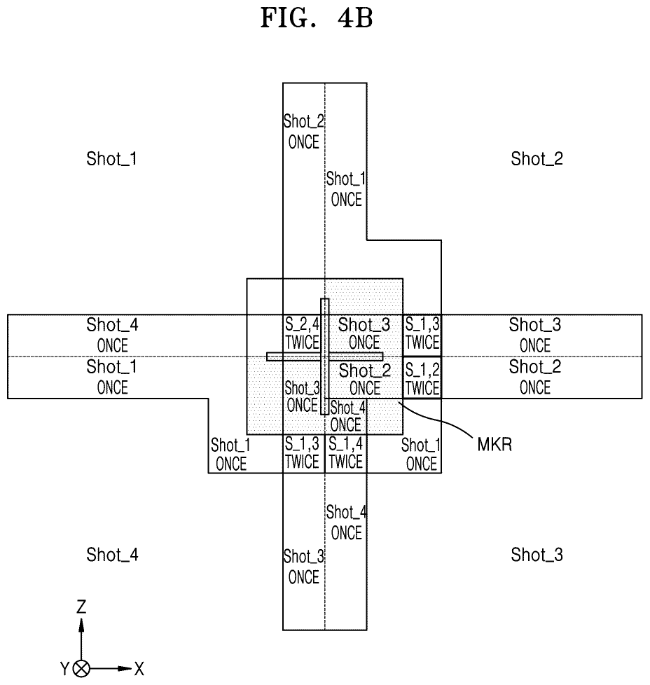

In an embodiment, the length of one side of the first corner region CR1 and the length of one side of the third corner region CR3 may each be equal to the first width d1 of each of the first to third buffer regions BFR1 to BFR3. Therefore, as described below with reference to FIGS. 4A and 4B, unintended overlapping exposures may be limited and/or prevented from being performed by the first to third buffer regions BFR1 to BFR3 each having the first width d1.

In an embodiment, a first horizontal length of the second corner region CR2 may be equal to the first width d1 set forth above, and a second horizontal length of the second corner region CR2 may be twice the first width d1 set forth above. That is, a length d7 of the portion of the third side S3 of the scribe lane region SLR, which contacts the second corner region CR2, may be equal to the first width d1 set forth above.

In an embodiment, the EUV photomask 100 may include a first auxiliary pattern region APR1, a second auxiliary pattern region APR2, a third auxiliary pattern region APR3, and a fourth auxiliary pattern region APR4. In the exposure of a mask pattern, which will be described below with reference to FIGS. 4A and 4B, each of the first to fourth auxiliary pattern regions APR1 to APR4 may be located in a region of the scribe lane region SLR, which corresponds to a region (see FIG. 4B) where an unintended overlapping exposure is repeated twice, outside the marker region MKR. Specifically, the first auxiliary pattern region APR1 may be arranged to contact the first blocking region BR1 and the first buffer region BFR1, the second auxiliary pattern region APR2 may be arranged to contact the first blocking region BR1 and the second buffer region BFR2, the third auxiliary pattern region APR3 may be arranged to contact the second blocking region BR2 and the first sub-buffer region BFR3a of the third buffer region BFR3, and the fourth auxiliary pattern region APR4 may be arranged to contact the third blocking region BR3 and the second sub-buffer region BFR3b of the third buffer region BFR3.

In an embodiment, each of the first to fourth auxiliary pattern regions APR1 to APR4 may transfer, onto the semiconductor substrate 200, a pattern designed by taking into account an energy latitude (EL) margin. For example, each of the first to fourth auxiliary pattern regions APR1 to APR4 may transfer a pattern causing the EL margin to be 20% or more. Here, the EL margin refers to a value quantified by measuring a degree of a change in pattern critical dimension (CD) according to a change in the amount of exposure in an exposure process. When the value of the EL margin is high, the degree of the change in pattern CD is small despite the change in the amount of exposure. That is, in an embodiment, because each of the first to fourth auxiliary pattern regions APR1 to APR4 transfers a pattern having a high value of the EL margin, even when an unintended overlapping exposure is repeated twice, pattern defects may be limited and/or prevented.

In an embodiment, each of the first to fourth auxiliary pattern regions APR1 to APR4 may have a square shape, and the length of one side of each of the first to fourth auxiliary pattern regions APR1 to APR4 may be equal to the first width d1 of each of the first to third buffer regions BFR1 to BFR3.

Referring to FIGS. 2 and 3, the EUV photomask 100 may include a mask substrate 110, a reflective layer 120, a capping layer 130, an absorbing layer 140, and a conductive layer 150. The mask substrate 110, reflective layer 120, capping layer 130, and absorbing layer 140 may be referred to as a mask structure MS on the conductive layer 150.

The mask substrate 110 may be formed of a material having a low coefficient of thermal expansion, such as silicon (Si). Alternatively, the mask substrate 110 may include quartz, glass, plastic, or the like.

The reflective layer 120 may be arranged on one surface 111 of the mask substrate 110. The reflective layer 120 may include at least two material layers having different refractive indices from each other and alternately stacked. For example, the reflective layer 120 may have a structure in which silicon layers and molybdenum layers are alternately stacked.

The reflective layer 120 may include a first reflective layer 120a on the main region MR and the scribe lane region SLR, a second reflective layer 120b on the buffer region BFR, and a third reflective layer 120c on the black border region BBR. In an embodiment, an optical density (OD) treatment may be performed on the third reflective layer 120c. The OD treatment may include, for example, laser annealing. By the OD treatment, the third reflective layer 120c may be made not to reflect light.

A portion of heat generated during the OD treatment may be conducted to the second reflective layer 120b. However, because the second reflective layer 120b has not perfectly undergone the OD treatment, the second reflective layer 120b may reflect a portion of light that is incident thereon.

That is, the third reflective layer 120c may have a lowest reflectance with respect to incident light, the first reflective layer 120a may have a highest reflectance with respect to incident light, and the second reflective layer 120b may have a medium reflectance, with respect to incident light, between the reflectance of the third reflective layer 120c and the reflectance of the first reflective layer 120a.

The capping layer 130 may be arranged on the reflective layer 120. The capping layer 130 may include, for example, a silicon layer. The capping layer 130 may protect the reflective layer 120 by limiting and/or preventing the reflective layer 120 from being oxidized. In an embodiment, unlike the example shown in FIG. 3, the capping layer 130 may be omitted.

The absorbing layer 140 may be arranged on the capping layer 130. For example, the absorbing layer 140 may be formed of, but is not limited to, TaN, TaNO, TaBO, Lr, or the like. The absorbing layer 140 may include a first absorbing pattern 140a on the main region MR, a second absorbing pattern 140b on the scribe lane region SLR, and an absorbing layer 140c on the buffer region BFR and the black border region BBR. The first absorbing pattern 140a may include a circuit layout pattern, and the second absorbing pattern 140b may include a test device layout pattern. The first absorbing pattern 140a and the second absorbing pattern 140b may have different pattern densities from each other. For example, the pattern density of the first absorbing pattern 140a may be greater than the pattern density of the second absorbing pattern 140b. Unlike the example shown in FIG. 3, a fine pattern (not shown) may be formed in a portion of the absorbing layer 140c located on the black border region BBR. The fine pattern may diffract or scatter other rays of light, for example, deep ultraviolet (DUV) light, except for EUV light out of incident light on the EUV photomask 100, thereby causing the other rays of light not to be reflected onto the semiconductor substrate 200. In this case, the pattern density of the fine pattern set forth above may be greater than the pattern density of the first absorbing pattern 140a and the pattern density of the second absorbing pattern 140b.

The conductive layer 150 may be arranged on the other surface 113 of the mask substrate 110. The conductive layer 150 may include, for example, a chromium-containing material, such as Cr, CrN, CrO, CrC, CrON, CrCN, CrOC, CrOCN, or the like. Due to the conductive layer 150, the EUV photomask 100 may be secured well by an electrostatic chuck.

An EUV photomask, which is used in photolithography processes using EUV light, generally includes a region (hereinafter referred to as a main region and a scribe lane region) for transferring patterns by reflecting incident light onto a semiconductor substrate, and a region (hereinafter referred to as a black border region) for causing the incident light not to be reflected onto the semiconductor substrate. In the case where the black border region undergoes heat treatment in a process of fabricating an EUV photomask, when the main region and the scribe lane region are in contact with the black border region, a portion of heat generated due to the heat treatment may be conducted to the main region and the scribe lane region. In this case, an unintended influence may be exerted on the reflection of the incident light performed by the main region and the scribe lane region, and thus, a pattern transferred onto the semiconductor substrate may be poor. To limit and/or prevent such an issue, a buffer region for limiting and/or preventing an influence due to the heat treatment may be arranged between the black border region and both of the main region and the scribe lane region. However, because the buffer region is not a region directly undergoing the heat treatment, a portion of light incident on the buffer region may be reflected onto the semiconductor substrate. Accordingly, due to the presence of the buffer region, when an EUV photomask according to the related art is used, unintended overlapping exposures may be performed on the semiconductor substrate.

On the other hand, in the EUV photomask 100 according to an embodiment, the first to third buffer regions BFR1 to BFR3 may be arranged apart from each other by adjusting the layout of the buffer region BFR, and the first to third corner regions CR1 to CR3 included in the black border region BBR may be respectively arranged in separated spaces between the first to third buffer regions BFR1 to BFR3. Therefore, unintended overlapping exposures due to the first to third buffer regions BFR1 to BFR3 may be limited and/or prevented even while limiting and/or preventing an issue due to the heat treatment performed on the black border region BBR, thereby improving pattern defects. This will be described below in more detail with reference to FIGS. 4A and 4B.

FIGS. 4A and 4B are diagrams each illustrating a method of transferring a mask pattern onto a substrate by exposure using an EUV photomask. FIG. 4A illustrates an example of transferring a mask pattern by exposure using an EUV photomask according to the related art, and FIG. 4B illustrates an example of transferring a mask pattern by exposure using an EUV photomask according to an embodiment of inventive concepts. In FIGS. 4A and 4B, a first shot, a second shot, a third shot, and a fourth shot are sequentially performed in the stated order, and the first to fourth shots are performed such that respective scribe lane regions of the first to fourth shots contact each other.

Referring to FIG. 4A, when a mask pattern is transferred by exposure using an EUV photomask according to the related art, it can be confirmed that three overlapping exposures have been unintentionally performed in the marker region MKR. For example, it can be confirmed that overlapping exposures due to the second, third, and fourth shots have been performed in the marker region MKR belonging to the first shot area, and that overlapping exposures due to the first, third, and fourth shots have been performed in the marker region MKR belonging to the second shot. As shown in FIG. 4A, when three overlapping exposures have been unintentionally performed in the marker region MKR, a portion of a photoresist composition, which is coated on a semiconductor substrate and corresponds to a region having undergone the overlapping exposures, may be dissolved during a development process, and thus, there may be a defect in a pattern formed on the semiconductor substrate.

On the other hand, referring to FIG. 4B, when a mask pattern is transferred by exposure using an EUV photomask according to an embodiment, it can be confirmed that only one or two overlapping exposures have been unintentionally performed in the marker region MKR. For example, it can be confirmed that overlapping exposures due to the second and fourth shots have been performed in the marker region MKR belonging to the first shot area, and that an overlapping exposure due to the third shot has been performed in the marker region MKR belonging to the second shot. As such, use of an EUV photomask according to an embodiment of inventive concepts may reduce the number of times an overlapping exposure is performed. Therefore, the dissolution of the photoresist composition during a development process may be limited and/or prevented, thereby improving a defect in a pattern formed on the semiconductor substrate.

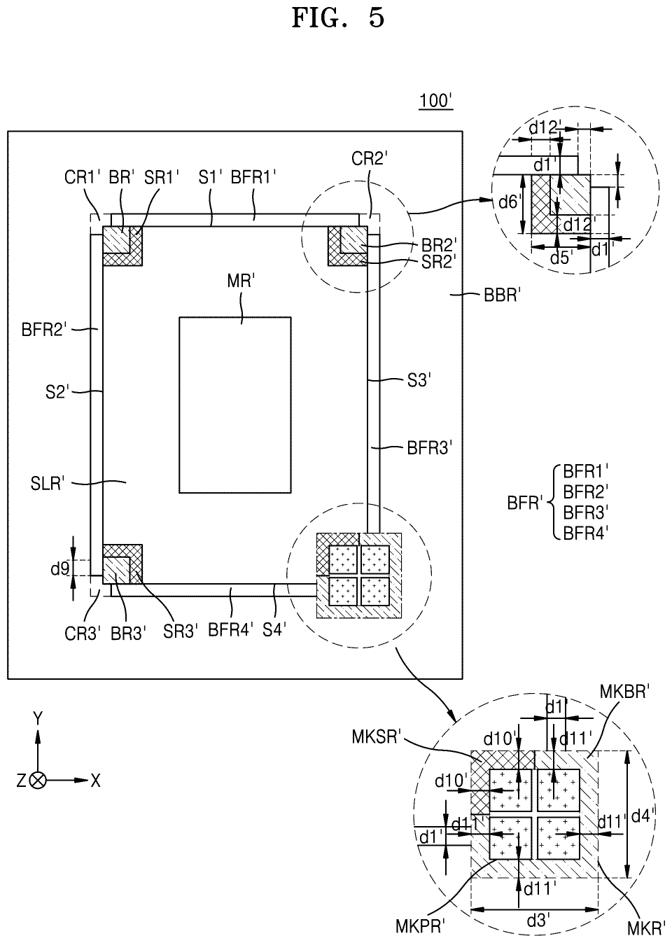

FIG. 5 is a plan view schematically illustrating an EUV photomask 100′ according to an embodiment. Because the components of the EUV photomask 100′ shown in FIG. 5 are respectively similar to the components of the EUV photomask 100 described with reference to FIG. 1, differences therebetween will be mainly described below.

Referring to FIG. 5, the EUV photomask 100′ may include a main region MR′, a scribe lane region SLR′ surrounding the main region MR′, a buffer region BFR′ arranged outside the scribe lane region SLR′ and having a first width d1′, and a black border region BBR′ outside the buffer region BFR′.

In an embodiment, the scribe lane region SLR′ may include a marker region MKR′ at one corner thereof. The marker region MKR′ may have, for example, a square shape. The marker region MKR′ may include a marker pattern region MKPR′, a marker blocking region MKBR′, and a marker variable region MKSR′.

The marker pattern region MKPR′ may transfer an alignment layout pattern. In an embodiment, the marker pattern region MKPR′ may transfer a pattern designed by taking into account an EL margin. For example, the marker pattern region MKPR′ may transfer a pattern for causing the EL margin to be 20% or more.

The marker blocking region MKBR′ may surround a portion of the marker pattern region MKPR′. Specifically, the marker blocking region MKBR′ may surround a portion of a perimeter of the marker pattern region MKPR′, the portion being close to the black border region BBR′ and third and fourth buffer regions BFR3′ and BFR4′. The marker blocking region MKBR′ may absorb all EUV light incident thereon.

In an embodiment, a width d11′ of the marker blocking region MKBR′ may be equal to the first width d1′ of the buffer region BFR′.

The marker variable region MKSR′ may surround the remaining portion of the perimeter of the marker pattern region MKPR′. Specifically, the marker variable region MKSR′ may surround a portion of the perimeter of the marker pattern region MKPR′, the portion being close to the scribe lane region SLR′. The marker variable region MKSR′ may reflect or may not reflect EUV light incident thereon, depending on the tone of the EUV photomask 100′. For example, when the UV photomask 100′ is a clear-tone mask, the marker variable region MKSR′ may reflect EUV light incident thereon. On the other hand, when the UV photomask 100′ is a dark-tone mask, the marker variable region MKSR′ may not reflect EUV light incident thereon. In an embodiment, a width d10′ of the marker blocking region MKBR′ may be equal to the first width d1′ of the buffer region BFR′.

In an embodiment, the scribe lane region SLR′ may further include first to third blocking regions BR1′ to BR3′ and first to third variable regions SR1′ to SR3′.

The first blocking region BR1′ may be located inside one corner of the scribe lane region SLR′, which corresponds to a first corner region CR1′. The first variable region SR1′ may surround a portion of the first blocking region BR1′. Specifically, the first variable region SR1′ may surround two sides of the first blocking region BR1′, which are closer to the scribe lane region SLR′, from among four sides of the first blocking region BR1′.

The second blocking region BR2′ may be located inside one corner of the scribe lane region SLR′, which corresponds to a second corner region CR2′. The second variable region SR2′ may surround a portion of the second blocking region BR2′. Specifically, the second variable region SR2′ may surround two sides of the second blocking region BR2′, which are closer to the scribe lane region SLR′, from among four sides of the second blocking region BR2′.

The third blocking region BR3′ may be located inside one corner of the scribe lane region SLR′, which corresponds to a third corner region CR3′. The third variable region SR3′ may surround a portion of the third blocking region BR3′. Specifically, the third variable region SR3′ may surround two sides of the third blocking region BR3′, which are closer to the scribe lane region SLR′, from among four sides of the third blocking region BR3′.

Each of the first, second, and third blocking regions BR1′, BR2′, and BR3′ may absorb all EUV light incident thereon.

Each of the first, second, and third variable regions SR1′, SR2′, and SR3′ may reflect or may not reflect EUV light incident thereon, depending on the tone of the EUV photomask 100′. For example, when the EUV photomask 100′ is a clear-tone mask, each of the first, second, and third variable regions SR1′, SR2′, and SR3′ may reflect EUV light incident thereon. On the other hand, when the EUV photomask 100′ is a dark-tone mask, each of the first, second, and third variable regions SR1′, SR2′, and SR3′ may not reflect EUV light incident thereon. In an embodiment, a width d12′ of each of the first to third variable regions SR1′ to SR3′ may be equal to the first width d1′ of the buffer region BFR′.

The buffer region BFR′ may include a first buffer region BFR1′, a second buffer region BFR2′, a third buffer region BFR3′, and a fourth buffer region BFR4′.

The first buffer region BFR1′ may contact a first side S1′ of the scribe lane region SLR′ and extend therealong. The second buffer region BFR2′ may contact a second side S2′ of the scribe lane region SLR′ and extend therealong. The third buffer region BFR3′ may contact a third side S3′ of the scribe lane region SLR′ and extend therealong. The fourth buffer region BFR4′ may contact a fourth side S4′ of the scribe lane region SLR′ and extend therealong.

Each of the first to fourth buffer regions BFR1′ to BFR4′ may have, for example, a rectangular shape.

In an embodiment, the first to fourth buffer regions BFR1′ to BFR4′ may be arranged apart from each other. As described below, separated spaces between the first, second, third, and fourth buffer regions BFR1′, BFR2′, BFR3′, and BFR4′ may be respectively filled with the first corner region CR1′, the second corner region CR2′, the third corner region CR3′, and the marker region MKR′.

In an embodiment, each of the first, second, third, and fourth buffer regions BFR1′, BFR2′, BFR3′, and BFR4′ may have the same first width d1′. In an embodiment, the first width d1′ set forth above may be about 4 μm to about 8 μm.

The black border region BBR′ may be arranged outside the first to fourth buffer regions BFR1′ to BFR4′. The black border region BBR′ may limit and/or prevent light incident on the EUV photomask 100′ from being reflected.

The black border region BBR′ may include the first corner region CR1′, the second corner region CR2′ and the third corner region CR3′.

The first corner region CR1′ may contact the first buffer region BFR1′, the second buffer region BFR2′, the first side S1′ of the scribe lane region SLR′, and the second side S2′ of the scribe lane region SLR′. The second corner region CR2′ may contact the first buffer region BFR1′, the third buffer region BFR3′, the first side S1′ of the scribe lane region SLR′, and the third side S3′ of the scribe lane region SLR′. The third corner region CR3′ may contact the second buffer region BFR2′, the fourth buffer region BFR4′, the second side S2′ of the scribe lane region SLR′, and the fourth side S4′ of the scribe lane region SLR′.

Each of the first to third corner regions CR1′ to CR3′ may have an L shape or a rotated L shape. Specifically, the third corner region CR3′ may have an L shape, the first corner region CR1′ may have a shape obtained by rotating an L shape clockwise by 90 degrees, and the second corner region CR2′ may have a shape obtained by rotating an L shape clockwise by 180 degrees.

In an embodiment, the width of each of the first, second, and third corner regions CR1′, CR2′, and CR3′ may be equal to the first width d1′ of the buffer region BFR′.

In the EUV photomask 100′ according to an embodiment, the first to fourth buffer regions BFR1′ to BFR4′ may be arranged apart from each other by adjusting the layout of the buffer region BFR′, and the first, second, and third corner regions CR1′, CR2′, and CR3′, which are included in the black border region BBR′, and the marker region MKR′ including the marker blocking region MBR′ may be respectively arranged in separated spaces between the first to fourth buffer regions BFR1′ to BFR4′. Therefore, unintended overlapping exposures due to the first to fourth buffer regions BFR1′ to BFR4′ may be limited and/or prevented even while limiting and/or preventing an influence due to the heat treatment performed on the black border region BBR′, thereby improving pattern defects.

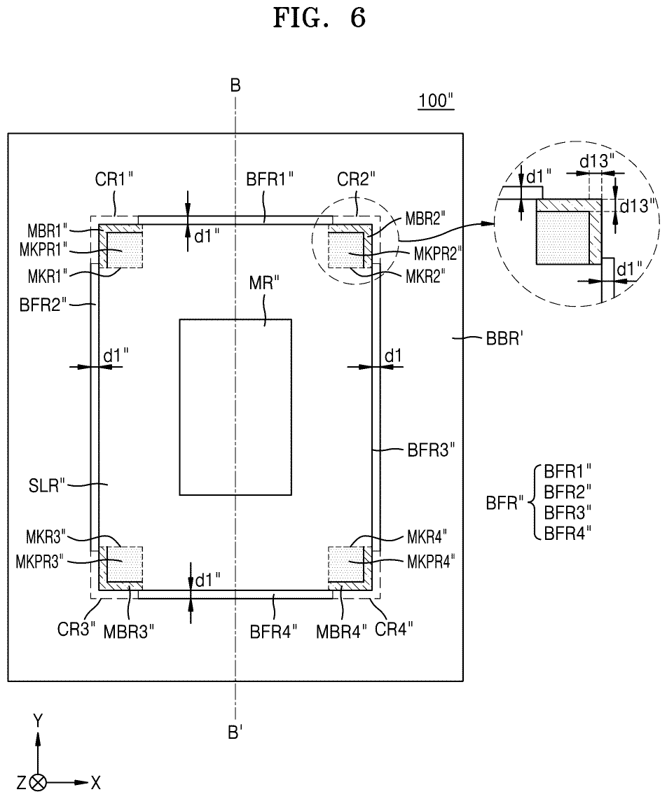

FIG. 6 is a plan view schematically illustrating an EUV photomask 100″ according to an embodiment. Because the components of the EUV photomask 100″ shown in FIG. 6 are respectively similar to the components of the EUV photomask 100 described with reference to FIG. 1, differences therebetween will be mainly described below.

Referring to FIG. 6, the EUV photomask 100″ may include a main region MR″, a scribe lane region SLR″ surrounding the main region MR″, a buffer region BFR″ arranged outside the scribe lane region SLR“and having a first width d1”, and a black border region BBR″ outside the buffer region BFR″.

The scribe lane region SLR″ may include first to fourth marker regions MKR1″ to MKR4″ respectively located at corners thereof. The first to fourth marker regions MKR1″ to MKR4″ may include first to fourth marker pattern regions MKPR1″ to MKPR4″ and first to fourth marker blocking regions MBR1″ to MBR4″, respectively. Each of the first to fourth marker regions MKR1″ to MKR4″ may have a square shape.

Each of the first to fourth marker pattern regions MKPR1″ to MKPR4″ may transfer an alignment layout pattern. Specifically, when the first to fourth shots are performed as in the method of transferring a mask pattern by exposure, which is described with reference to FIGS. 4A and 4B, the fourth marker pattern region MKPR4″ may be transferred by the first shot, the third marker pattern region MKPR3″ may be transferred by the second shot, the first marker pattern region MKPR1″ may be transferred by the third shot, and the second marker pattern region MKPR2″ may be transferred by the fourth shot, whereby the alignment layout pattern having a cross shape may be transferred to a central region of the first to fourth shots.

In an embodiment, each of the first to fourth marker pattern regions MKPR1″ to MKPR4″ may transfer a pattern designed by taking into account an EL margin. For example, the marker pattern region MKPR″ may transfer a pattern for causing the EL margin to be 20% or more.

The first to fourth marker blocking regions MBR1″ to MBR4″ may respectively surround portions of the first to fourth marker pattern regions MKPR1″ to MKPR4″. Specifically, each of the first, second, third, and fourth marker blocking regions MBR1″, MBR2″, MBR3″, and MBR4″ may surround two sides, which are closer to each corner of the scribe lane region SLR″, of each of the first, second, third, and fourth maker pattern regions MKPR1″, MKPR2″, MKPR3″, and MKPR4″ from among four sides thereof, respectively.

In an embodiment, a width d13″ of each of the first to fourth marker blocking regions MBR1″ to MBR4″ may be equal to the first width d1″ of the buffer region BFR″. The marker blocking region MBR″ may absorb all EUV light incident thereon.

The buffer region BFR″ may include a first buffer region BFR1″, a second buffer region BFR2″, a third buffer region BFR3″, and a fourth buffer region BFR4″.

The first buffer region BFR1″ may contact a first side S1″ of the scribe lane region SLR″ and extend therealong. The second buffer region BFR2″ may contact a second side S2″ of the scribe lane region SLR″ and extend therealong. The third buffer region BFR3″ may contact a third side S3″ of the scribe lane region SLR″ and extend therealong. The fourth buffer region BFR4″ may contact a fourth side S4″ of the scribe lane region SLR″ and extend therealong.

Each of the first to fourth buffer regions BFR1″ to BFR4″ may have, for example, a rectangular shape.

In an embodiment, the first to fourth buffer regions BFR1″ to BFR4″ may be arranged apart from each other. As described below, separated spaces between the first to fourth buffer regions BFR1″ to BFR4″ may be filled with first to fourth corner regions CR1″ to CR4″, respectively.

In an embodiment, each of the first to fourth buffer regions BFR1″ to BFR4″ may have the same first width d1″. In an embodiment, the first width d1″ set forth above may be about 4 μm to about 8 μm.

The black border region BBR″ may be arranged outside the first to fourth buffer regions BFR1″ to BFR4″.

The black border region BBR″ may include the first corner region CR1″, the second corner region CR2″, the third corner region CR3″, and the fourth corner region CR4″.

The first corner region CR1″ may contact the first buffer region BFR1″, the second buffer region BFR2″, the first side S1″ of the scribe lane region SLR″, and the second side S2″ of the scribe lane region SLR″. The second corner region CR2″ may contact the first buffer region BFR1″, the third buffer region BFR3″, the first side S1″ of the scribe lane region SLR″, and the third side S3″ of the scribe lane region SLR″. The third corner region CR3″ may contact the second buffer region BFR2″, the fourth buffer region BFR4″, the second side S2″ of the scribe lane region SLR″, and the fourth side S4″ of the scribe lane region SLR″. The fourth corner region CR4″ may contact the third buffer region BFR3″, the fourth buffer region BFR4″, the third side S3″ of the scribe lane region SLR″, and the fourth side S4″ of the scribe lane region SLR″.

Each of the first to fourth corner regions CR1″ to CR4″ may have an L shape or a rotated L shape. Specifically, the third corner region CR3″ may have an L shape, the first corner region CR1″ may have a shape obtained by rotating an L shape clockwise by 90 degrees, the second corner region CR2″ may have a shape obtained by rotating an L shape clockwise by 180 degrees, and the fourth corner region CR4″ may have a shape obtained by rotating an L shape clockwise by 270 degrees.

In an embodiment, the width of each of the first to fourth corner regions CR1″ to CR4″ may be equal to the first width d1″ of the buffer region BFR″.

In an embodiment, with respect to the imaginary central line B-B′ passing through the center of the main region MR″,

the first corner region CR1″ and the second corner region CR2″ may be line-symmetric to each other, and the third corner region CR3″ and the fourth corner region CR4″ may be line-symmetric to each other.

In the EUV photomask 100″ according to an embodiment, the first to fourth buffer regions BFR1″ to BFR4″ may be arranged apart from each other by adjusting the layout of the buffer region BFR″, and the first to fourth corner regions CR1″ to CR4″ included in the black border region BBR″ may be respectively arranged in separated spaces between the first to fourth buffer regions BFR1″ to BFR4″. Therefore, unintended overlapping exposures due to the first to fourth buffer regions BFR1″ to BFR4″ may be limited and/or prevented even while limiting and/or preventing an influence due to the heat treatment performed on the black border region BBR″, thereby improving pattern defects.

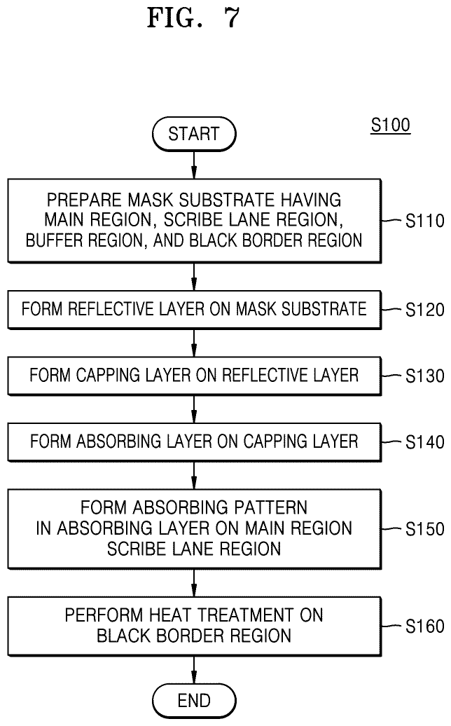

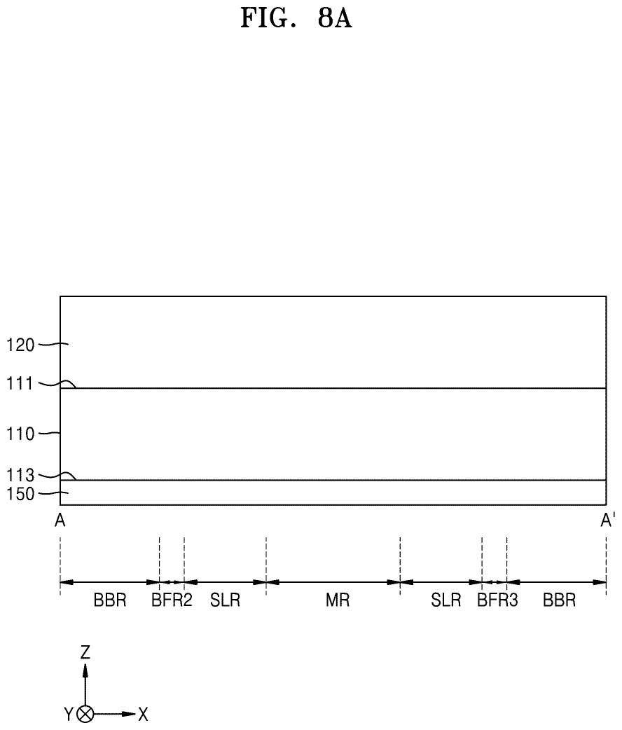

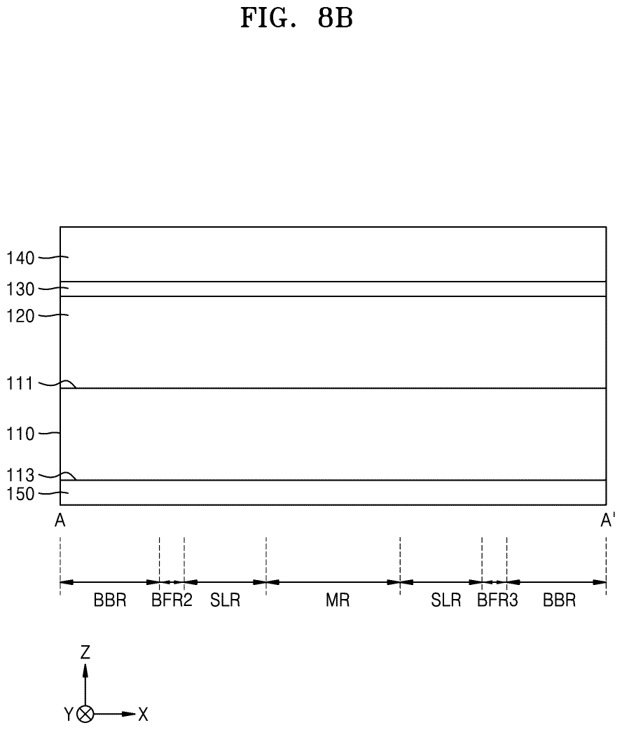

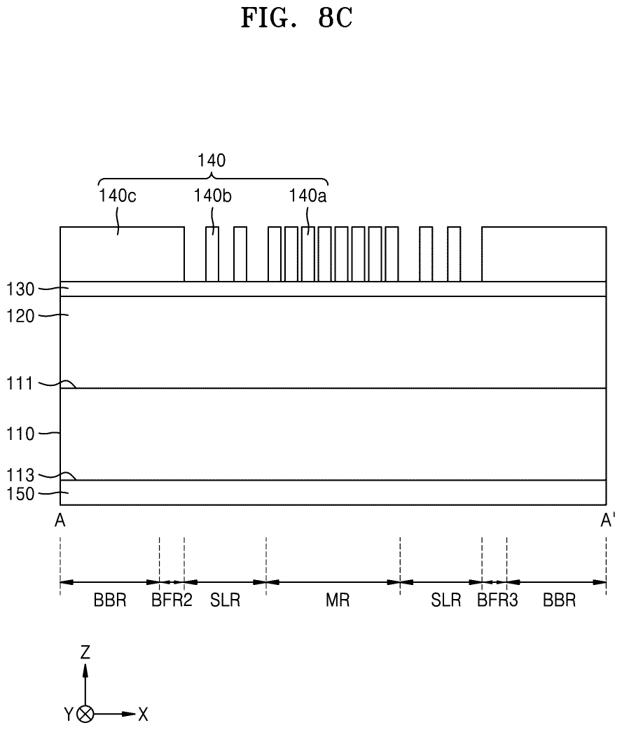

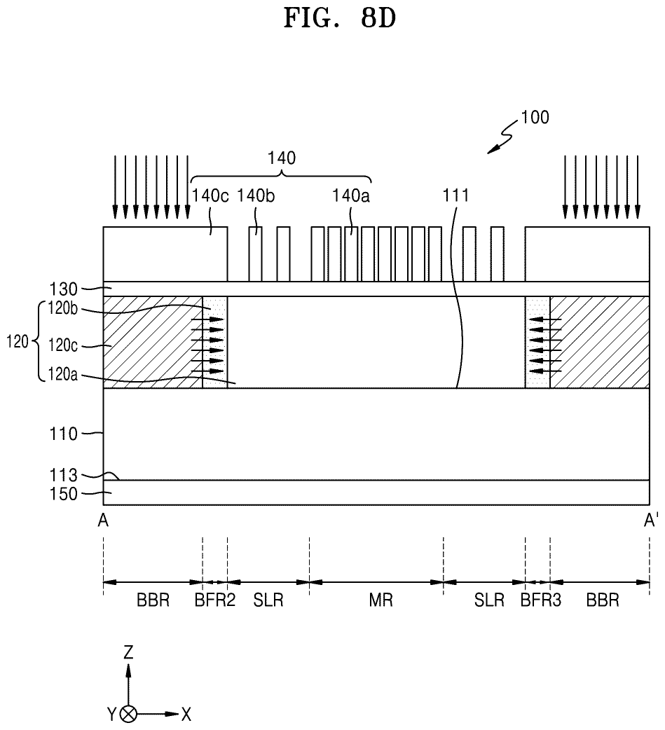

FIG. 7 is a flowchart schematically illustrating a method of fabricating the EUV photomask 100 according to an embodiment. FIGS. 8A to 8D are cross-sectional views schematically illustrating processes of the method of fabricating the EUV photomask 100 according to an embodiment, respectively. Although FIGS. 7 and 8A to 8D are illustrated based on the EUV photomask 100 shown in FIG. 2, inventive concepts are not limited thereto.

Referring to FIG. 7, the mask substrate 110 having the main region MR, the scribe lane region SLR, the buffer region BFR, and the black border region BBR may be prepared (S110).

Referring to FIGS. 7, 8A, and 8B, after operation S110, the reflective layer 120, the capping layer 130, and the absorbing layer 140 may be sequentially formed, in the stated order, on one surface 111 of the mask substrate 110 (S120, S130, and S140). Each of the reflective layer 120, the capping layer 130, and the absorbing layer 140 may be formed by a deposition process. The deposition process may include, but is not limited to, for example, physical vapor deposition (PVD), chemical vapor deposition (CVD), ion-beam deposition, or the like.

After operation S140, the conductive layer 150 may be formed on the other surface 113 of the mask substrate 110. The conductive layer 150 may be formed by, for example, a deposition process, such as CVD, PVD, or ion-beam deposition. However, inventive concepts are not limited thereto, and, for example, after operation S110, before operation S120, the conductive layer 150 may be formed on the other surface 113 of the mask substrate 110.

Referring to FIGS. 7 and 8C, after operations S120, S130, and S140 are performed in the stated order, absorbing patterns (for example, 140a and 140b) may be formed in the absorbing layers 140 on the main region MR and the scribe lane region SLR (S150). Here, the first absorbing pattern 140a may include a circuit layout pattern, and the second absorbing pattern 140b may include a test device layout pattern. In an embodiment, operation S150 may further include forming a fine pattern (not shown) in the absorbing layer 140 on the black border region BBR. In this case, the fine pattern prevents other incident light except for EUV light from being reflected to the semiconductor substrate 200 (see FIG. 1A) by diffracting or scattering the other incident light.

Referring to FIGS. 7 and 8D, after operation S150, heat treatment may be performed on the black border region BBR (S160). The arrows in FIG. 8D represent the movement of heat generated by the heat treatment. By the heat treatment, a third reflective layer 120c on the black border region BBR may be made not to reflect EUV light. The heat treatment may be performed by, for example, laser annealing. The heat treatment may change, for example, silicon (Si), which is included in the reflective layer 120 on the black border region BBR, into silicon nitride (SiN).

A portion of the heat generated during the heat treatment may be conducted to the buffer region BFR. Accordingly, a second reflective layer 120b on the buffer region BFR may also partially undergo the heat treatment.

In operation S160, the layout of both the buffer region BFR and the black border region BBR may be determined by design data for the EUV photomask 100, which is obtained before operation S110. The design data may be obtained by designing a layout for a required circuit and then transferring design data, which is obtained through optical proximity correction (OPC), as mask tape-out (MTO) design data. After the MTO design data is obtained, mask data preparation (MDP) may be performed based thereon. After the MDP is performed, operation S110 may be performed.

According to the EUV photomask 100 fabricated according to FIGS. 7 and 8A to 8D, as described with reference to FIGS. 2 and 3, the layout of the buffer region BFR and the black border region BBR may be adjusted, thereby limiting and/or preventing unintended overlapping exposures and improving pattern defects due to overlapping exposures.

While inventive concepts have been particularly shown and described with reference to embodiments thereof, it will be understood that various changes in form and details may be made therein without departing from the spirit and scope of the following claims.

What is claimed is:

1. An extreme ultraviolet (EUV) photomask comprising:
a mask structure including a main region, a scribe lane region surrounding the main region, a plurality of buffer regions outside the scribe lane region and apart from each other, and a black border region outside the plurality of buffer regions,
the plurality of buffer regions including a first buffer region, a second buffer region, and a third buffer region,
a first width of the first buffer region, a first width of the second buffer region, and a first width of the third buffer region being equal to each other,
the scribe lane region including a marker region at one corner thereof,
the first buffer region contacting a first side of the scribe lane region and extending therealong,
the second buffer region contacting a second side of the scribe lane region and extends therealong,
the third buffer region including a first sub-buffer region, a second sub-buffer region, and a third sub-buffer region,
the first sub-buffer region contacting a third side of the scribe lane region and extending therealong,
the second sub-buffer region contacting a fourth side of the scribe lane region and extending therealong,
the third sub-buffer region surrounding the marker region and contacting the first sub-buffer region and the second sub-buffer region, and
the black border region including a first corner region, a second corner region, and a third corner region,
the first corner region contacting the first buffer region and the second buffer region,
the second corner region contacting the first buffer region, the first sub-buffer region, and the third side of the scribe lane region, and
the third corner region contacting the second buffer region and the second sub-buffer region.

2. The EUV photomask of claim 1, wherein a first horizontal length of the first corner region, a second horizontal length of the first corner region, a first horizontal length of the third corner region, and a second horizontal length of the third corner region are equal to the first width of the first buffer region, the first width of the second buffer region, and the first width of the third buffer region.

3. The EUV photomask of claim 1, wherein
a first horizontal length of the second corner region is equal to each of the first width of the first buffer region, the first width of the second buffer region, and the first width of third buffer region, and
a second horizontal length of the second corner region is twice the first width of the first buffer region, twice the first width of the second buffer region, and twice the first width of the third buffer region.

4. The EUV photomask of claim 1, wherein
the scribe lane region comprises a first blocking region, a second blocking region, and a third blocking region,
the first blocking region is inside a first corner of the scribe lane region corresponding to the first corner region,
the second blocking region is inside a second corner of the scribe lane region corresponding to the second corner region, and
the third blocking region is inside a third corner of the scribe lane region corresponding to the third corner region.

5. The EUV photomask of claim 4, wherein
a first horizontal length of each of the first blocking region, the second blocking region, and the third blocking region is 0.5 times a first horizontal length of the marker region, and
a second first horizontal length of each of the first blocking region, the second blocking region, and the third blocking region is 0.5 times a second horizontal length of the marker region.

6. The EUV photomask of claim 4, wherein
the scribe lane region comprises a first auxiliary pattern region, a second auxiliary pattern region, a third auxiliary pattern region, and a fourth auxiliary pattern region,
the first auxiliary pattern region contacts the first blocking region and the first buffer region,
the second auxiliary pattern region contacts the first blocking region and the second buffer region,
the third auxiliary pattern region contacts the second blocking region and the second sub-buffer region of the third buffer region, and
the fourth auxiliary pattern region contacts the third blocking region and the first sub-buffer region of the third buffer region, and
each of the first auxiliary pattern region, the second auxiliary pattern region, the third auxiliary pattern region, and the fourth auxiliary pattern region include an auxiliary pattern designed by taking into account an energy latitude (EL) margin.

7. The EUV photomask of claim 6, wherein
a first horizontal length of the first auxiliary pattern region, a second horizontal length of the first auxiliary pattern region, a first horizontal length of the second auxiliary pattern region, a second horizontal length of the second auxiliary pattern region, a first horizontal length of the third auxiliary pattern region, a second horizontal length of the third auxiliary pattern region, a first horizontal length of the fourth auxiliary pattern region, and a second horizontal length of the fourth auxiliary pattern region are each equal to the first width of the first buffer region, the first width of the second buffer region, and the first width of the third buffer region.

8. The EUV photomask of claim 1, wherein the first width of the first buffer region, the first width of the second buffer region, and the first width of the third buffer region are each 4 μm to 8 μm.

9. The EUV photomask of claim 1, wherein
a reflectance with respect to incident light in the black border region is lower than a reflectance with respect to incident light in the plurality of buffer regions, and
a reflectance with respect to incident light in the main region is higher than the reflectance with respect to incident light in the plurality of buffer regions.

10. The EUV photomask of claim 9, wherein
the mask structure includes a reflective layer,
in the black border region of the mask structure, the reflective layer includes a nitride.

11. An extreme ultraviolet (EUV) photomask comprising:
a mask structure including a main region, a scribe lane region surrounding the main region, a plurality of buffer regions outside the scribe lane region and apart from each other, and a black border region outside the plurality of buffer regions,
the plurality of buffer regions including a first buffer region, a second buffer region, a third buffer region, and a fourth buffer region,
a first width of the first buffer region, a first width of the second buffer region, a first width of the third buffer region, and a first width of the fourth buffer region being equal to each other,
the scribe lane region including a marker region at one corner thereof,
the marker region including a marker pattern region, a marker blocking region surrounding a portion of the marker pattern region, and a marker variable region surrounding a remaining portion of the marker pattern region,
the first buffer region contacting a first side of the scribe lane region and extending therealong,
the second buffer region contacting a second side of the scribe lane region and extending therealong,
the third buffer region contacting a third side of the scribe lane region and extending therealong, and the third buffer region contacting the marker region,
the fourth buffer region contacting a fourth side of the scribe lane region and extending therealong, and the fourth buffer region contacting the marker region,
the black border region including a first corner region, a second corner region, and a third corner region,
the first corner region contacting the first buffer region and the second buffer region,
the second corner region contacting the first buffer region and the third buffer region, and
the third corner region contacting the second buffer region and the fourth buffer region.

12. The EUV photomask of claim 11, wherein a width of the first corner region, a width of the second corner region, and a width of the third corner region are each equal to the first width of the first buffer region, the first width of the second buffer region, the first width of the third buffer region, and the first width of the fourth buffer region.

13. The EUV photomask of claim 11, wherein
the scribe lane region comprises a first blocking region, a first variable region surrounding a portion of the first blocking region, a second blocking region, a second variable region surrounding a portion of the second blocking region, a third blocking region, and a third variable region surrounding a portion of the third blocking region,
the first blocking region is inside a corner of the scribe lane region corresponding to the first corner region,
the second blocking region is inside a corner of the scribe lane region corresponding to the second corner region, and
the third blocking region inside a corner of the scribe lane region corresponding to the third corner region.

14. The EUV photomask of claim 13, wherein a width of the first variable region, a width of the second variable region, and a width of the third variable region are each equal to the first width of the first buffer region, the first width of the second buffer region, the first width of the third buffer region, and the first width of the fourth buffer region.

15. The EUV photomask of claim 11, wherein a width of the marker blocking region and a width of the marker variable region are each equal to the first width of the first buffer region, the first width of the second buffer region, the first width of the third buffer region, and the first width of the fourth buffer region.

16. The EUV photomask of claim 11, wherein the marker pattern region comprises a marker pattern designed by taking into account an energy latitude (EL) margin.

17. An extreme ultraviolet (EUV) photomask comprising:
a mask structure including a main region, a scribe lane region surrounding the main region and having a rectangular shape, a plurality of buffer regions outside the scribe lane region and apart from each other, and a black border region outside the plurality of buffer regions,
the plurality of buffer regions including a first buffer region, a second buffer region, a third buffer region, and a fourth buffer region,
a first width of the first buffer region, a first width of the second buffer region, a first width of the third buffer region, and a first width of the fourth buffer region being equal to each other,
the scribe lane region including a first marker region, a second marker region, a third marker region, and a fourth marker region, respectively located at corners of the scribe lane region,
the first marker region, the second marker region, the third marker region, and the fourth marker regions each including a marker pattern region and a marker blocking region surrounding a portion of the marker pattern region,
the first buffer region contacting a first side of the scribe lane region and extending therealong,
the second buffer region contacting a second side of the scribe lane region and extending therealong,
the third buffer region contacting a third side of the scribe lane region and extending therealong,
the fourth buffer region contacting a fourth side of the scribe lane region and extending therealong,
the black border region including a first corner region, a second corner region, a third corner region, and a fourth corner region,
the first corner region contacting the first buffer region, the second buffer region, and the first marker region,
the second corner region contacting the first buffer region, the third buffer region, and the second marker region,
the third corner region contacting the second buffer region, the fourth buffer region, and the third marker region, and
the fourth corner region contacting the third buffer region, the fourth buffer region, and the fourth marker region.

18. The EUV photomask of claim 17, wherein a width of the first corner region, a width of the second corner region, a width of the third corner region, and a width of the fourth corner region each are equal to the first width of the first buffer region, the first width of the second buffer region, the first width of the third buffer region, and the first width of the fourth buffer region.

19. The EUV photomask of claim 17, wherein
in the first marker region, the second marker region, the third marker region, and the fourth marker region, respectively, a width of the marker blocking region is equal to each of the first width of the first buffer region, the first width of the second buffer region, the first width of the third buffer region, and the first width of the fourth buffer region.

20. The EUV photomask of claim 17, wherein,
with respect to a line passing through a center of the main region,
the first corner region and the second corner region are line-symmetric to each other, and
the third corner region and the fourth corner region are line-symmetric to each other.
